(19) United States
(12) Patent Application Publication
(10) Pub. No.: US 2025/0185356 A1
(43) Pub. Date: Jun. 5, 2025

(54) SELF-ALIGNED BACKSIDE GATE CUT DIELECTRIC WITH AIR GAP

(71) Applicant: INTERNATIONAL BUSINESS MACHINES CORPORATION, ARMONK, NY (US)

(72) Inventors: Tsung-Sheng Kang, Ballston Lake, NY (US); Tao Li, Slingerlands, NY (US); Ruilong Xie, Niskayuna, NY (US); Nicolas Jean Loubet, GUILDERLAND, NY (US)

(21) Appl. No.: 18/528,863

(22) Filed: Dec. 5, 2023

(51) Int. Cl. H01L 27/092; H01L 29/06; H01L 29/417; H01L 29/423; H01L 29/775; H01L 29/786

(52) U.S. Cl. CPC H10D 84/85; H10D 30/43; H10D 30/6729; H10D 30/6735; H10D 30/6757; H10D 62/121

(57) ABSTRACT

A semiconductor structure including a first nanosheet transistor device, a second nanosheet transistor device, a dielectric gate cut structure between and electrically isolating the first nanosheet transistor device from the second nanosheet transistor device, where a first portion of the dielectric gate cut structure has a positive tapered profile, and a second portion of the dielectric gate cut structure has a negative tapered profile.

### BACKGROUND

The present invention generally relates to semiconductor structures, and more particularly to nanosheet transistor structures having self-aligned backside gate cut dielectric with an air gap.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a first nanosheet transistor device, a second nanosheet transistor device, a dielectric gate cut structure between and electrically isolating the first nanosheet transistor device from the second nanosheet transistor device, where a first portion of the dielectric gate cut structure has a positive tapered profile, and a second portion of the dielectric gate cut structure has a negative tapered profile.

According to another embodiment of the present invention, a semiconductor structure is provided. The semiconductor structure may include a first nanosheet stack, a second nanosheet stack, a self-aligned gate cut structure between and electrically isolating a first gate associated with the first nanosheet stack and a second gate associated with the second nanosheet stack, where a first portion of the self-aligned gate cut structure has a positive tapered profile, and a second portion of the self-aligned gate cut structure has a negative tapered profile.

According to another embodiment of the present invention, a semiconductor structure is provided. The semiconductor structure may include first set of nanosheet channels surrounded by a first gate structure, second set of nanosheet channels surrounded by a second gate structure, a self-aligned gate cut structure between and electrically isolating the first gate structure from the second gate structure, where a first portion of the self-aligned gate cut structure has a positive tapered profile, and a second portion of the self-aligned gate cut structure has a negative tapered profile, and where a topmost surface of the second portion of the self-aligned gate cut structure is substantially flush with topmost surfaces of adjacent shallow trench isolation regions.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIGS. 2, 3, and 4 are cross-sectional views of the semiconductor structure during an intermediate step of a method of fabricating nanosheet transistor structures according to an exemplary embodiment;

FIGS. 5, 6, and 7 are cross-sectional views of the semiconductor structure after forming a gate cut mask and patterning gate cut trenches according to an exemplary embodiment;

FIGS. 8, 9, and 10 are cross-sectional views of the semiconductor structure after forming gate cut structures including frontside gate cut liners and frontside gate cut insulators according to an exemplary embodiment;

FIGS. 11, 12, and 13 are cross-sectional views of the semiconductor structure after forming middle-of-line and back-end-of-line, and securing a carrier wafer according to an exemplary embodiment;

FIGS. 14, 15, and 16 are cross-sectional views of the semiconductor structure after flipping the assembly and recessing the substrate according to an exemplary embodiment;

FIGS. 17, 18, and 19 are cross-sectional views of the semiconductor structure after removing and recessing remaining portions of the substrate according to an exemplary embodiment;

FIGS. 20, 21, and 22 are cross-sectional views of the semiconductor structure after forming a protective capping layer forming a first sacrificial liner according to an exemplary embodiment;

FIGS. 23, 24, and 25 are cross-sectional views of the semiconductor structure after forming backside access openings according to an exemplary embodiment;

FIGS. 26, 27, and 28 are cross-sectional views of the semiconductor structure after forming a self-aligned backside gate cut dielectric and backside isolation features according to an exemplary embodiment;

FIGS. 29, 30, and 31 are cross-sectional views of the semiconductor structure after removing the protective capping layer, removing remaining portions of the top semiconductor layer, and depositing a backside dielectric according to an exemplary embodiment;

FIGS. 32, 33, and 34 are cross-sectional views of the semiconductor structure after forming a backside contact mask and backside contact trenches according to an exemplary embodiment;

FIGS. 35, 36, and 37 are cross-sectional views of the semiconductor structure after removing the placeholders exposed by the backside contact trenches according to an exemplary embodiment; and

FIGS. 38, 39, and 40 are cross-sectional views of the semiconductor structure after forming backside contact structures and backside wiring layers according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. Some transistor designs attempt to conserve valuable space by moving power lines from the back-end-of-line on a frontside of the wafer to the backside power delivery network on a backside of the wafer. In doing so, the space previously occupied by the power lines, which is typically at or above the cell boundary, is occupied by additional signal lines. However, forming electrical connections between the new signal lines at the cell boundary and corresponding transistors presents unique challenges. For example, one way to access signal lines at cell boundaries is to extend middle-of-line source drain contacts laterally into the cell boundary. Such source drain contacts would naturally intrude upon any gate cut dielectric (CT) present between adjacent transistors or groups of transistors. Air gaps which may be present within the gate cut dielectric (CT) are reasonably beneficial and help minimize capacitance; however, if the source drain contacts extend laterally into the cell boundary such air gaps would fill with contact metallization during fabrication thereby defeating all benefits previously enjoyed by the presence of the air gaps.

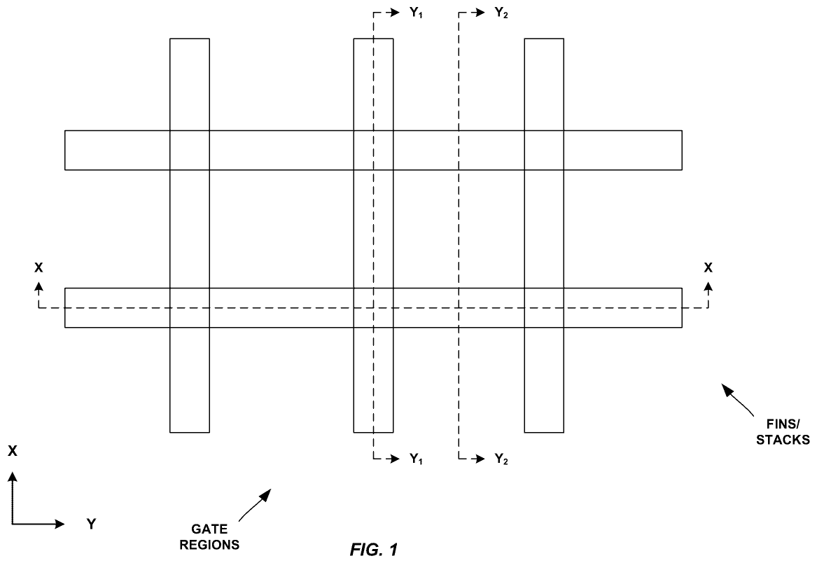

The present invention generally relates to semiconductor structures, and more particularly to nanosheet transistor structures having self-aligned backside gate cut dielectric with an air gap. More specifically, the nanosheet transistor structures and associated method disclosed herein enable a novel solution for providing self-aligned backside device contacts with self-aligned backside gate cut dielectric. Exemplary embodiments of nanosheet transistor structures having self-aligned backside device contacts with self-aligned backside gate cut dielectric are described in detail below by referring to the accompanying drawings in FIGS. 1 to 40. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIGS. 1-40 represent cross section views oriented as indicated in FIG. 1

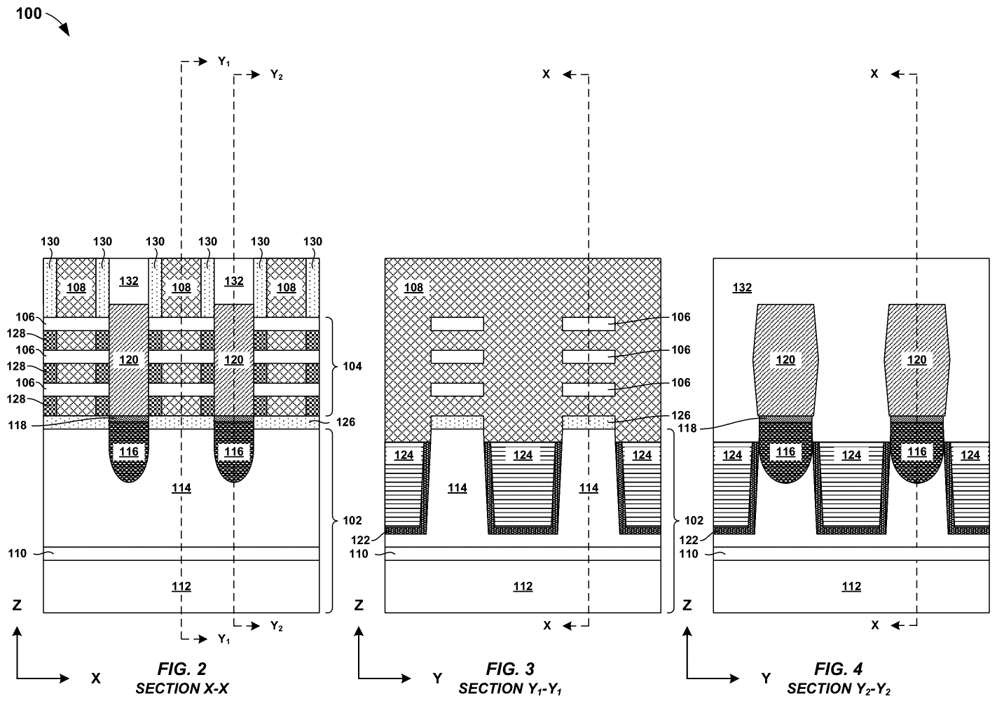

Referring now to FIGS. 2, 3, and 4, a structure 100 is shown during an intermediate step of a method of fabricating a nanosheet transistor structure according to an embodiment of the invention. FIG. 2 depicts a cross-sectional view of the structure 100 shown in FIGS. 3 and 4 taken along line X-X, FIG. 3 depicts a cross-sectional view of the structure 100 shown in FIG. 2 taken along line Y₁-Y₁, and FIG. 4 depicts a cross-sectional view of the structure 100 shown in FIG. 2 taken along line Y₂-Y₂.

The structure 100 illustrated in FIGS. 2-4 includes an array of nanosheet transistors formed on a substrate 102 in accordance with known techniques. As illustrated, the array of nanosheet transistors includes nanosheet stacks 104. Each nanosheet stack 104 includes a plurality of silicon channels 106 surrounded by a single gate 108. For purposes of orientation, the substrate 102 is herein referred to as being on a “backside” of the structure 100 and the array of nanosheet transistors are herein referred to as being on a “frontside” of the structure 100. Further, certain features may be described herein as having a relative position with respect to the frontside or backside of the structure 100.

The substrate 102 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 102 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, both the etch stop layer 110 and the base substrate 112 are sacrificial and will not remain in the final structure. As such, thickness of the top semiconductor layer 114, and similarly the position of the etch stop layer 110, approximately denote a relative position of subsequently formed backside features, such as, backside wiring layers or a backside power delivery network.

The structure 100 further includes placeholders 116, buffer layers 118, and source drain regions 120 generally arranged between adjacent nanosheet stacks 104, as illustrated.

The placeholders 116 are formed by filling self-aligned openings in the top semiconductor layer 114 between adjacent nanosheet stacks 104 with a sacrificial material according to known techniques. Specifically, after filling, the sacrificial material is recessed to create the placeholders 116 according to known techniques. In an embodiment, the sacrificial material is silicon germanium or amorphous silicon epitaxially grown from the surfaces of the top semiconductor layer 114. In another embodiment, the sacrificial material is SiC, SiOC deposited using, for example, chemical vapor deposition (CVD) or plasma enhanced CVD (PECVD) and subsequently recessed using, for example, reactive ion etching (RIE). Other suitable deposition and recessing techniques may be used provided they do not induce a physical or chemical change to the silicon channels 106.

The buffer layers 118 are formed on top of the placeholders 116 according to known techniques. Specifically, an etch stop material is formed directly on top of the placeholders 116. In an embodiment, the etch stop material can be any silicon-based material suitable to provide needed etch stop properties during backside processing. For example, the buffer layers 118 are designed to allow the subsequent removal of the placeholders 116 selective to the source drain regions 120.

The source drain regions 120 are formed on top of the buffer layer 118 according to known techniques. Specifically, the source drain regions 120 are disposed between adjacent nanosheet stacks 104 in direct contact with exposed ends of the silicon channels 106. More specifically, the source drain regions 120 may be epitaxially grown from the exposed ends of the silicon channels 106 according to known techniques.

The structure 100 further includes shallow trench isolation regions (hereinafter “STI regions”) which extend partially into the substrate 102 below the array of nanosheet transistors. In general, the STI regions may each include an isolation liner 122 and an isolation fill 124. For example, the isolation liner 122 is SiN, SiON, or SiOCN, and the isolation fill 124 is silicon oxide (SiO) or silicon nitride (SiN).

The structure 100 further includes stack spacers 126, inner spacers 128, and gate spacers 130.

The stack spacers 126 are disposed directly beneath the nanosheet stacks 104 separating them from the substrate 102. Specifically, for example, a relatively thin layer of silicon nitride is conformally deposited prior to forming the nanosheet stacks 104. In some embodiments, for example, the stack spacers 126 may be composed of SiN, SiBCN, SiOCN, SiOC, or any other combination of low-k materials. Like the buffer layers 118, the stack spacers 126 can provide etch selectivity during backside processing.

The inner spacers 128 are disposed between alternate channels (106), and laterally separate the gates 108 from the source drain regions 120, as illustrated. The inner spacers 128 provide necessary electrical insulation between the gates 108 and the source drain regions 120.

The gate spacers 130 are added to define the channel length and the source drain regions, and ultimately electrically insulate the gates 108 from subsequently formed structures, such as, for example, source drain contact structures. The gate spacers 130 are critical for electrically insulating the gates 108 from the source drain regions 120 or subsequently formed contact structures. In at least one embodiment, the gate spacers 130 include silicon nitride, silicon boron nitride, silicon carbon nitride, silicon boron carbon nitride, or other known equivalents.

Finally, the structure 100 further includes a dielectric layer 132 directly above and surrounding the source drain regions 120. The dielectric layer 132 is composed of any suitable interlayer dielectric material, such as, for example, oxides such as silicon oxide (SiOₓ), nitrides such as silicon nitride (SiₓN_{y}), and/or low-κ materials such as SiCOH or SiBCN. In another embodiment, is composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In yet another embodiment, a self-planarizing material such as a spin-on glass (SOG) or a spin-on low-k dielectric material such as SiLK™ can be used to form the dielectric layer 132. Using a self-planarizing dielectric material as the dielectric layer 132 can avoid the need to perform a subsequent planarizing step. After formation, top surfaces of the dielectric layer 132 are typically made flush, or substantially flush, with top surfaces of the gates 108 and the gate spacers 130 by chemical mechanical polishing techniques.

Although only a limited number of components, devices, or structures are shown, embodiments of the present invention shall not be limited by any quantity otherwise illustrated or discussed herein.

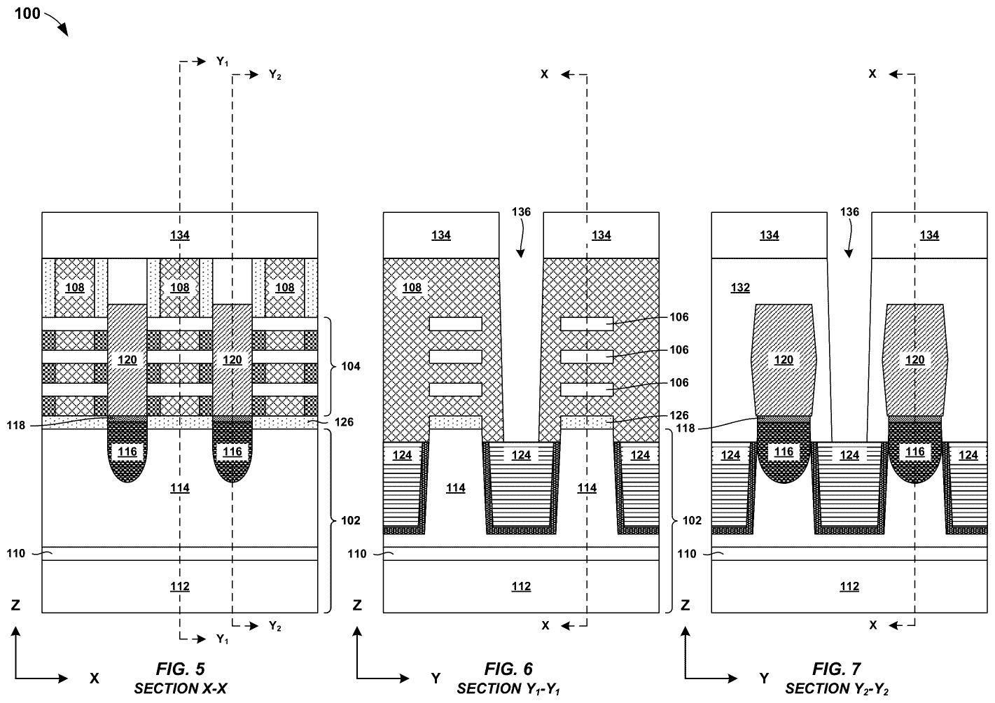

Referring now to FIGS. 5, 6, and 7, the structure 100 is shown after forming a gate cut mask 134 and patterning gate cut trenches 136 according to an embodiment of the invention. FIG. 5 depicts a cross-sectional view of the structure 100 shown in FIGS. 6 and 7 taken along line X-X, FIG. 6 depicts a cross-sectional view of the structure 100 shown in FIG. 5 taken along line Y₁-Y₁, and FIG. 7 depicts a cross-sectional view of the structure 100 shown in FIG. 5 taken along line Y₂-Y₂.

First, a hard mask material is deposited on the structure 100. According to an exemplary embodiment, the hard mask material is deposited onto the dielectric layer 132 and the gates 108, and then patterned into a plurality of individual hard masks, hereinafter the gate cut mask 134. The gate cut mask 134, and subsequently formed gate cut trenches 136, define gate regions of individual nanosheet stacks 104 or groups of nanosheet stacks 104.

Next, the pattern created by the gate cut mask 134 is transferred into the dielectric layer 132 and the gates 108 to form the gate cut trenches 136, as illustrated. Specifically, portions of the dielectric layer 132 and the gates 108 are etched or removed selective to the gate cut mask 134, as illustrated. The portions of the dielectric layer 132 and the gates 108 can be removed using a silicon RIE process. In some instances where a gate dielectric is present, an additional clean process is used to remove exposed portions of the gate dielectric. Additionally, the gate cut trenches 136 generally define a width of the individual gates in the y-direction, as best illustrated in FIGS. 6 and 7.

Critical to the present invention, the isolation fill 124 of the STI regions must be exposed at bottoms of the gate cut trenches 136, as illustrated. Doing so will be necessary to form the self-aligned backside gate cut dielectric in subsequent steps. Further, the gate cut trenches 136 will have a positive tapered profile in which a lateral width at a bottom is less than a lateral width at the top, as illustrated. The positive tapered profile of the gate cut trenches 136 is a direct result of etching the gate cut trenches 136 from the frontside, or otherwise during frontside processing, as will be appreciated by persons having skill in the art.

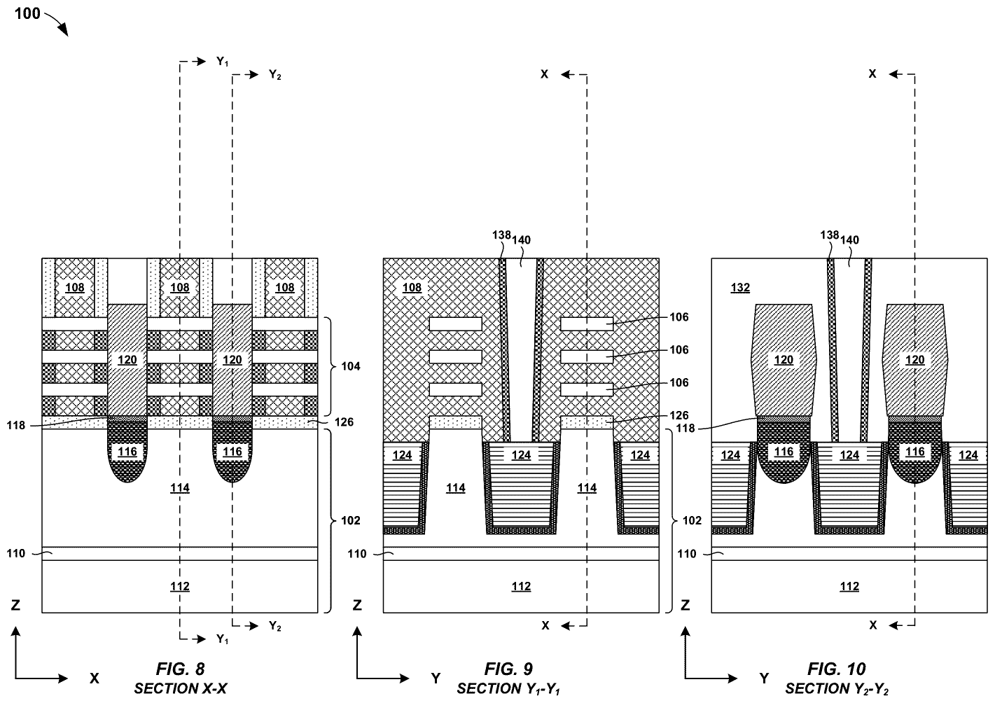

Referring now to FIGS. 8, 9, and 10, the structure 100 is shown after forming gate cut structures including frontside gate cut liners 138 and frontside gate cut insulators 140 according to an embodiment of the invention. FIG. 8 depicts a cross-sectional view of the structure 100 shown in FIGS. 9 and 10 taken along line X-X, FIG. 9 depicts a cross-sectional view of the structure 100 shown in FIG. 8 taken along line Y₁-Y₁, and FIG. 10 depicts a cross-sectional view of the structure 100 shown in FIG. 8 taken along line Y₂-Y₂.

First, the frontside gate cut liners 138 are formed along opposite sidewalls of the gate cut trenches 136 according to known techniques. Specifically, a dielectric liner material is conformally deposited across exposed surfaces of the structure 100 including within the gate cut trenches 136. After deposition, known directional etching techniques, for example reactive ion etching, may be used to remove excess portions of the dielectric liner material from horizontal surfaces. Doing so will remove portions of the dielectric liner material from bottoms of the gate cut trenches 136 thereby exposing the isolation fill 124 of the STI regions. In an embodiment, the frontside gate cut liners 138 are silicon nitride; however, other suitable dielectric liner materials may also be used.

Next, the frontside gate cut insulators 140 is deposited on top of the frontside gate cut liners 138 and the isolation fill 124 of the STI regions, thereby filling the gate cut trenches 136 according to known techniques. Specifically, a dielectric fill material is blanket deposited across the structure 100 including within the gate cut trenches 136. After deposition, known chemical mechanical polishing may be used to remove excess portions of the dielectric fill material from top surfaces of the structure 100. After polishing, topmost surfaces of the frontside gate cut insulators 140 are flush, or substantially flush with topmost surfaces of the gates 108 and the dielectric layer 132. Both the frontside gate cut liners 138 and the frontside gate cut insulators 140 may be referred to herein as frontside gate cut structures.

According to the embodiments disclosed herein, individual gate regions defined by the frontside gate cut structures may include a single nanosheet stack 104 or multiple nanosheet stacks 104 having a common gate 108. Additionally, the different nanosheet stacks 104 separated by the frontside gate cuts structures may be N-type, P-type, or any combination thereof. Finally, the frontside gate cut structures can be positioned anywhere according to a desired design, and are not necessarily limited to the positions and configurations depicted and described herein.

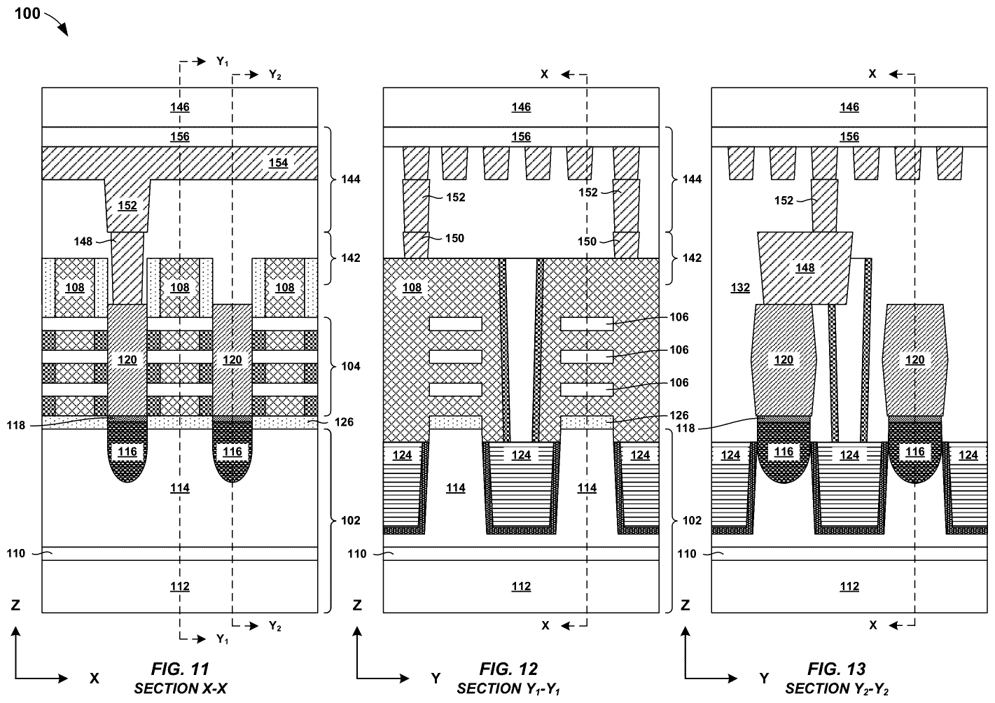

Referring now to FIGS. 11, 12, and 13, the structure 100 is shown after forming middle-of-line 142 and back-end-of-line 144, and securing a carrier wafer 146 according to an embodiment of the invention. FIG. 11 depicts a cross-sectional view of the structure 100 shown in FIGS. 12 and 13 taken along line X-X, FIG. 12 depicts a cross-sectional view of the structure 100 shown in FIG. 11 taken along line Y₁-Y₁, and FIG. 13 depicts a cross-sectional view of the structure 100 shown in FIG. 11 taken along line Y₂-Y₂.

The middle-of-line 142 includes source drain contacts 148 and gate contacts 150 which may be generally referred to as middle-of-line contacts. The source drain contacts 148 and the gate contacts 150 are formed according to known techniques.

The back-end-of-line 144 includes vias 152 and metal lines 154 which may be generally referred to as back-end-of-line interconnects. The vias 152 and the metal lines 154 are formed according to known techniques. According to embodiments of the present invention, the metal lines 154 represent signal lines.

Typically, the space in the back-end-of-line 144 directly above the cell boundary was occupied by power rails or power lines, and signal lines were arranged directly above devices to facilitate easy via connections between source drain contacts and the signal lines. Here, no power rail is necessary in the back-end-of-line 144 and the source drain contact 148 (see FIG. 13) is permitted to extend laterally into the cell boundary. Said differently, the source drain contact 148 (see FIG. 13) of the present invention extends laterally into the frontside gate cut structure.

Finally, the carrier wafer 146 is secured to a top of the structure 100 according to an embodiment of the invention. The carrier wafer 146 is attached, or removably secured, to the back-end-of-line 144. In general, and not depicted, the carrier wafer 146 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 146 according to known techniques.

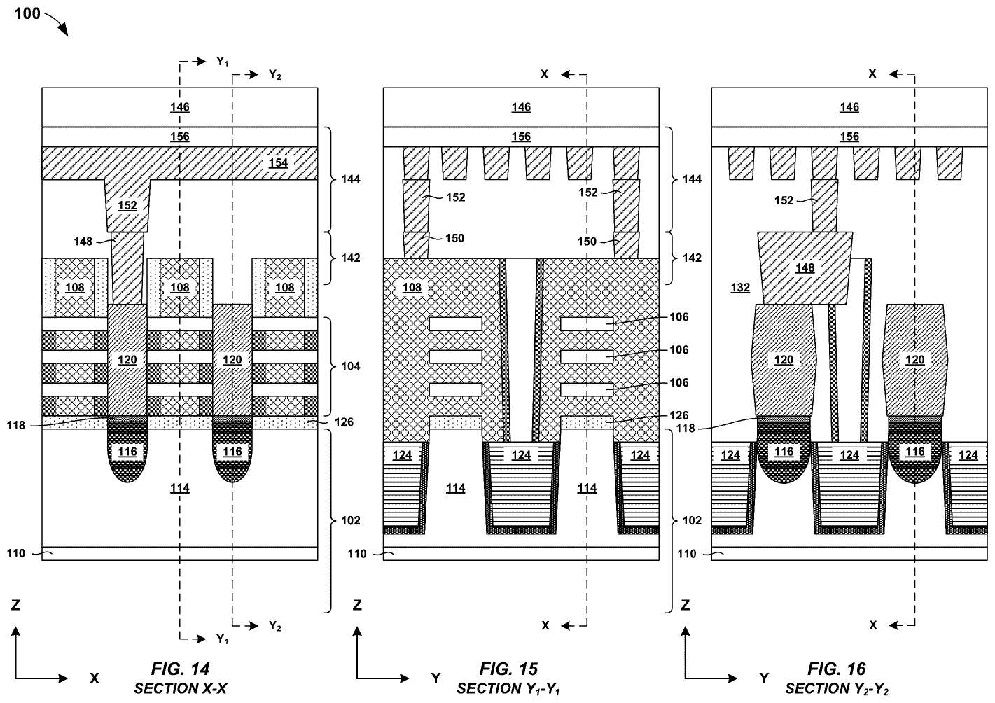

Referring now to FIGS. 14, 15, and 16, the structure 100 is shown after flipping the assembly and recessing the substrate 102 according to an embodiment of the invention. FIG. 14 depicts a cross-sectional view of the structure 100 shown in FIGS. 15 and 16 taken along line X-X, FIG. 15 depicts a cross-sectional view of the structure 100 shown in FIG. 14 taken along line Y₁-Y₁, and FIG. 16 depicts a cross-sectional view of the structure 100 shown in FIG. 14 taken along line Y₂-Y₂.

First, the structure 100 is flipped 180 degrees to prepare for backside processing. In general, backside processing includes fabrication or processing of the structure 100 opposite the active device and wiring layers. Next, the substrate 102 is recessed according to known techniques. Specifically, the base substrate 112 is recessed or completely removed to expose the etch stop layer 110, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

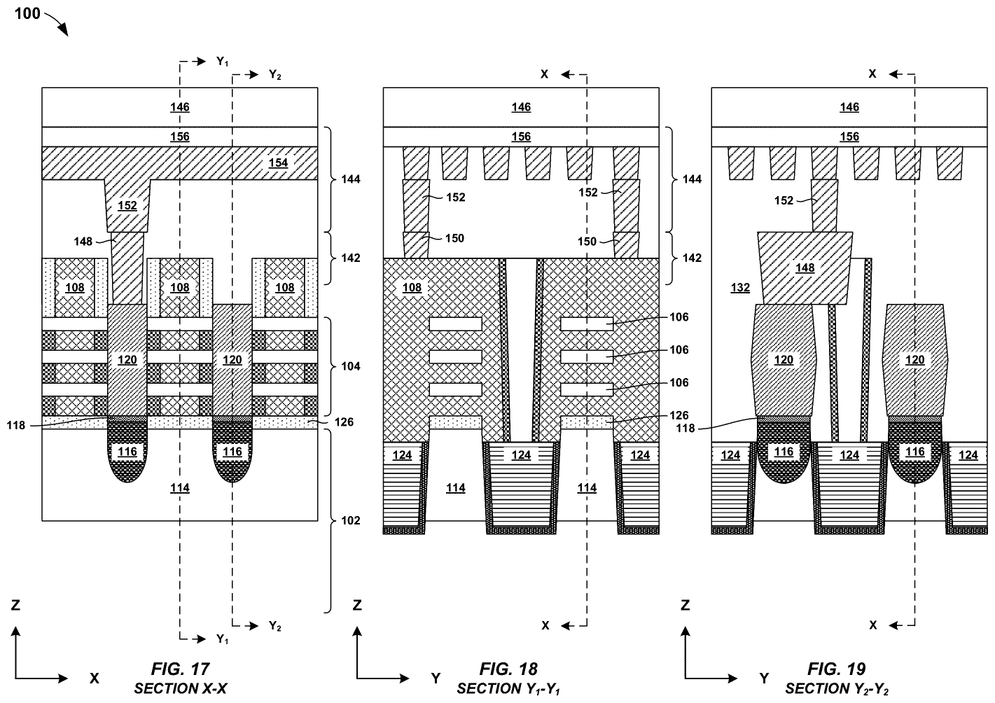

Referring now to FIGS. 17, 18, and 19, the structure 100 is shown after removing and recessing remaining portions of the substrate 102 according to an embodiment of the invention. FIG. 17 depicts a cross-sectional view of the structure 100 shown in FIGS. 18 and 19 taken along line X-X, FIG. 18 depicts a cross-sectional view of the structure 100 shown in FIG. 17 taken along line Y₁-Y₁, and FIG. 19 depicts a cross-sectional view of the structure 100 shown in FIG. 17 taken along line Y₂-Y₂.

First, the etch stop layer 110 is selectively removed and the top semiconductor layer 114 is recessed according to known techniques. Specifically, the etch stop layer 110 is removed selective to the top semiconductor layer 114, and the top semiconductor layer 114 is recessed selective to the STI regions. According to embodiments of the present invention the top semiconductor layer 114 is recessed to a depth sufficient to all for the subsequent formation of a protective capping layer.

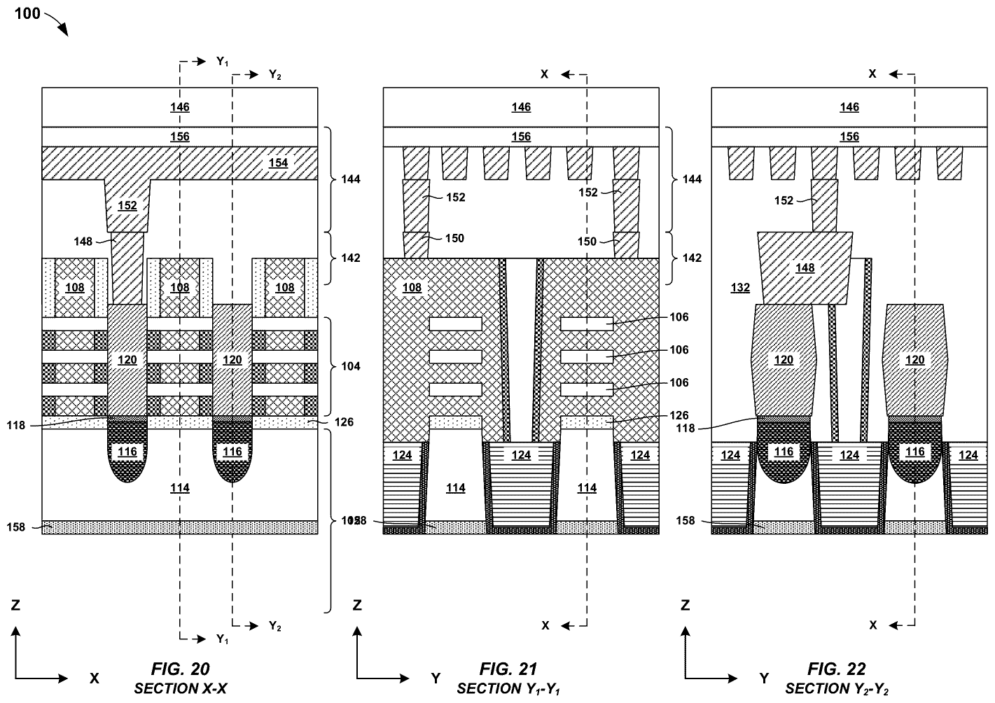

Referring now to FIGS. 20, 21, and 22, the structure 100 is shown after forming a protective capping layer 158 according to an embodiment of the invention. FIG. 20 depicts a cross-sectional view of the structure 100 shown in FIGS. 21 and 22 taken along line X-X, FIG. 21 depicts a cross-sectional view of the structure 100 shown in FIG. 20 taken along line Y₁-Y₁, and FIG. 22 depicts a cross-sectional view of the structure 100 shown in FIG. 20 taken along line Y₂-Y₂.

The protective capping layer 158 is blanket deposited on the backside of the structure 100 according to known techniques. Specifically, a dielectric capping material is blanket deposited across the structure 100 including within the spaces formed by recessing the top semiconductor layer 114 selective to the STI regions. After deposition, known chemical mechanical polishing may be used to remove excess portions of the dielectric capping material from backside surfaces of the structure 100. After polishing, bottommost surfaces of the protective capping layer 158 are flush, or substantially flush, with bottommost surfaces of the STI regions.

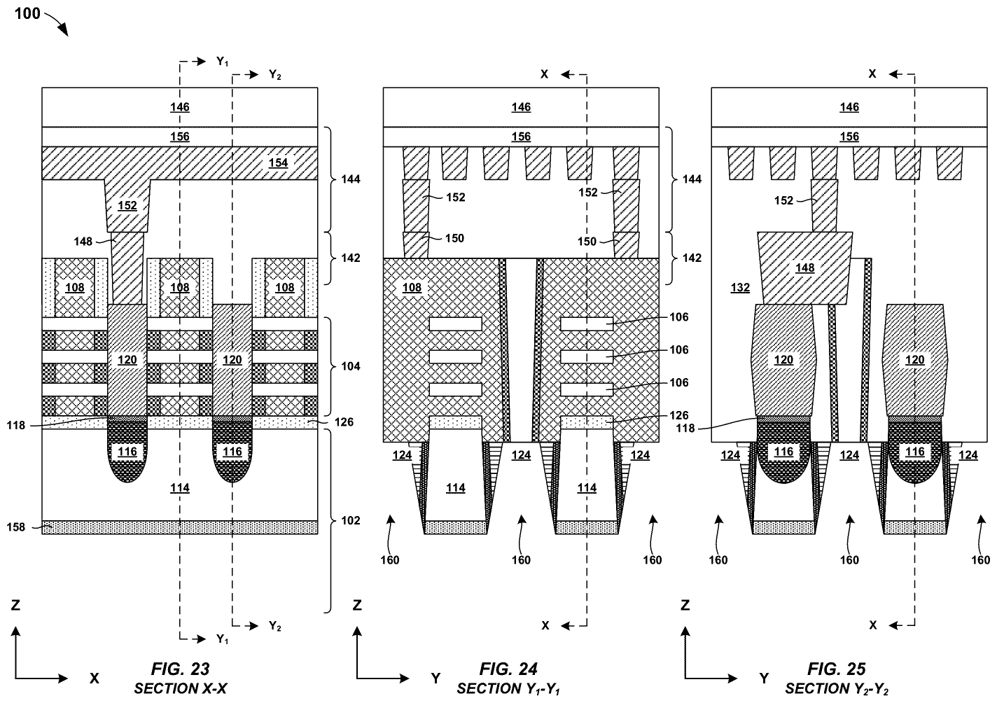

Referring now to FIGS. 23, 24, and 25, the structure 100 is shown after forming backside access openings 160 according to an embodiment of the invention. FIG. 23 depicts a cross-sectional view of the structure 100 shown in FIGS. 24 and 25 taken along line X-X, FIG. 24 depicts a cross-sectional view of the structure 100 shown in FIG. 23 taken along line Y₁-Y₁, and FIG. 25 depicts a cross-sectional view of the structure 100 shown in FIG. 23 taken along line Y₂-Y₂.

Portions of the STI regions are selectively removed according to known techniques. Specifically, portions of the isolation liner 122 and the isolation fill 124 are removed selective to the protective capping layer 158 to create the backside access openings 160, as illustrated. The portions of the isolation liner 122 and the isolation fill 124 can be removed using a silicon RIE process. Additionally, due to the nature of selective etching a width of the backside access openings 160 in the y-direction is predominantly controlled by the original size and spacing of the STI regions. As a result, portions of the isolation fill 124 may remain, as illustrated.

Critical to the present invention, the frontside gate cut insulators 140 must be exposed after forming the backside access openings 160, as illustrated. It is further noted, the frontside gate cut insulators 140 may not be exposed in all of the backside access openings 160, as illustrated. Exposing the frontside gate cut insulators 140 is necessary to selectively remove frontside gate cut insulators 140 in subsequent steps. Furthermore, the backside access openings 160 will have a negative tapered profile in which a lateral width at a bottom is greater than a lateral width at the top, as illustrated. The negative tapered profile of the backside access openings 160 is a direct result of etching the backside access openings 160 from the backside, or otherwise during backside processing, as will be appreciated by persons having skill in the art.

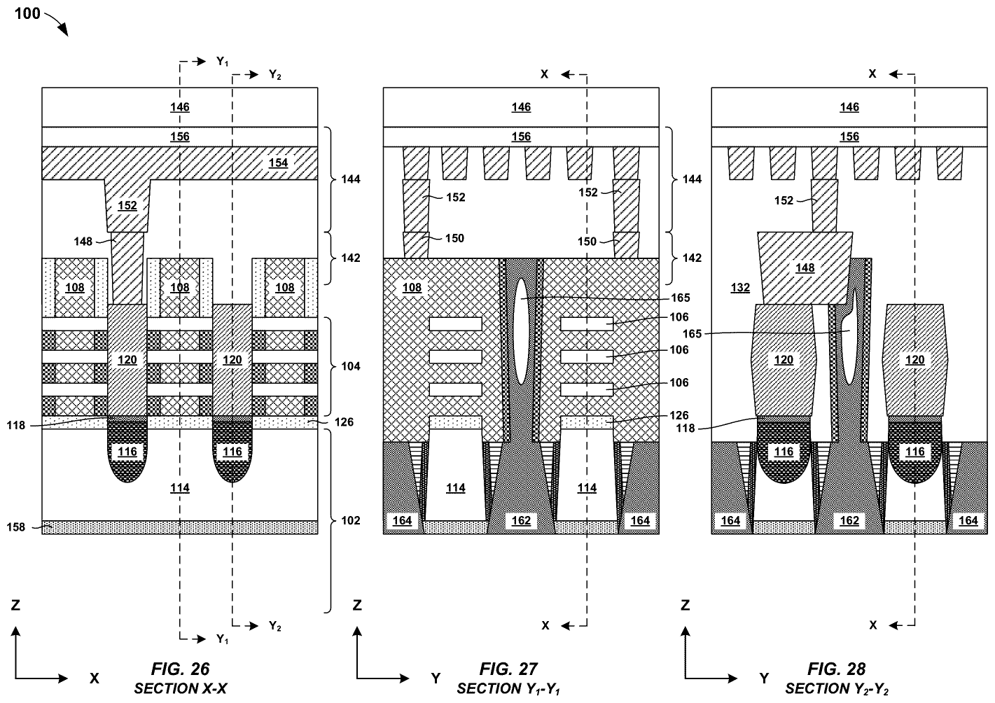

Referring now to FIGS. 26, 27, and 28, the structure 100 is shown after removing the frontside gate cut insulators 140 and forming a self-aligned backside gate cut dielectric 162 and backside isolation features 164 according to an embodiment of the invention. FIG. 26 depicts a cross-sectional view of the structure 100 shown in FIGS. 27 and 28 taken along line X-X, FIG. 27 depicts a cross-sectional view of the structure 100 shown in FIG. 26 taken along line Y₁-Y₁, and FIG. 28 depicts a cross-sectional view of the structure 100 shown in FIG. 26 taken along line Y₂-Y₂.

First, the frontside gate cut insulators 140 are removed according to known techniques. Specifically, the frontside gate cut insulators 140 exposed within the backside access openings 160 is removed selective to both the isolation liner 122, the frontside gate cut liners 138, and any other surrounding materials. The frontside gate cut insulators 140 can be removed using a silicon RIE process. In doing so, certain of the backside access openings 160 are enlarged or made deeper (not shown).

Next, the enlarged backside access opening (not shown), as well as the backside access openings 160, are backfilled with a second dielectric fill material thereby forming the self-aligned backside gate cut dielectric 162 and the backside isolation features 164, respectively. Specifically, the second dielectric fill material is blanket deposited across the structure 100 including within the enlarged backside access opening and the backside access openings 160. After deposition, known chemical mechanical polishing may be used to remove excess portions of the second dielectric fill material from top surfaces of the structure 100. After polishing, bottommost surfaces of the self-aligned backside gate cut dielectric 162 and the backside isolation features 164 will be flush, or substantially flush with bottommost surfaces of the protective capping layer 158, as illustrated. It is noted that although the self-aligned backside gate cut dielectric 162 and the backside isolation features 164 are both made from the same dielectric material, only the self-aligned backside gate cut dielectric 162 extends between adjacent devices into the frontside of the structure 100. The self-aligned backside gate cut dielectric 162 may alternatively be referred to as a dielectric gate cut structure or a self-aligned gate cut structure.

Unique to the present invention, filling the enlarged backside access opening from the backside as described above will, in most cases, create an airgap 165 or void, embedded within the self-aligned backside gate cut dielectric 162 as illustrated. The creation and existence of the airgap 165 is beneficial and minimizes capacitance. Also, to the present invention, a top portion of the self-aligned backside gate cut dielectric 162 will have a positive tapered profile consistent with the positive tapered profile of the gate cut trenches 136, and a bottom portion of the self-aligned backside gate cut dielectric 162 will have a negative tapered profile consistent with the negative tapered profile of the backside access openings 160, as illustrated. Yet another unique feature of the present invention, the backside isolation features 164 will have a negative tapered profile consistent with the negative tapered profile of the backside access openings 160, as illustrated.

In an embodiment, both the self-aligned backside gate cut dielectric 162 and the backside isolation features 164 are made from SiO, SiON, or other suitable dielectric materials deposited using, for example, chemical vapor deposition (CVD) or plasma enhanced CVD (PECVD).

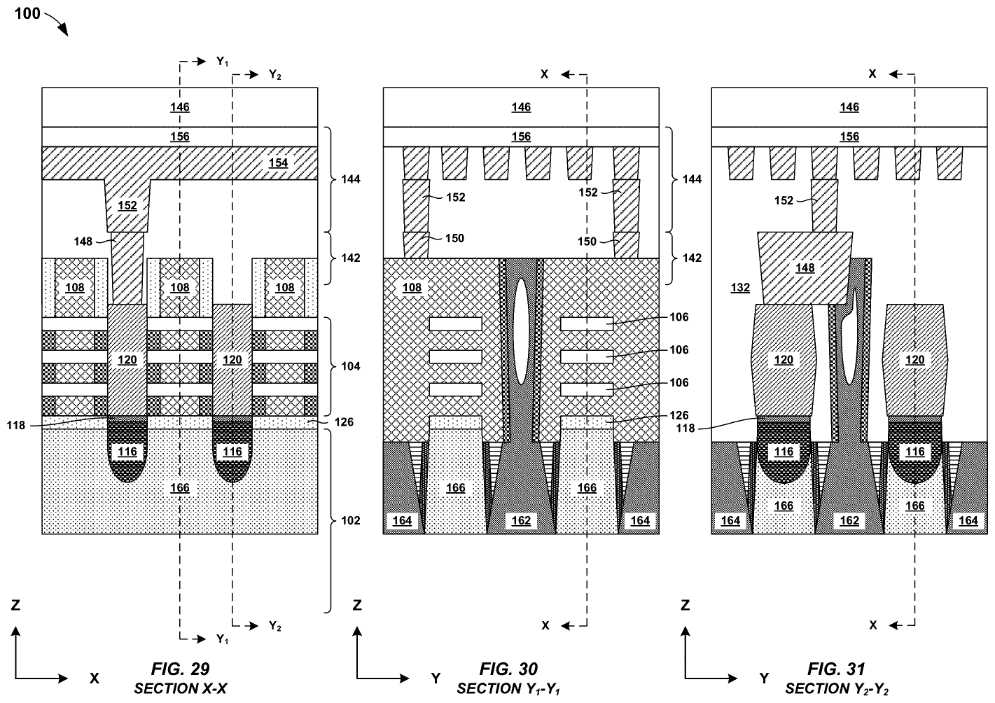

Referring now to FIGS. 29, 30, and 31, the structure 100 is shown after removing the protective capping layer 158, removing remaining portions of the top semiconductor layer 114, and depositing a backside dielectric 166 according to an embodiment of the invention. FIG. 29 depicts a cross-sectional view of the structure 100 shown in FIGS. 30 and 31 taken along line X-X, FIG. 30 depicts a cross-sectional view of the structure 100 shown in FIG. 29 taken along line Y₁-Y₁, and FIG. 31 depicts a cross-sectional view of the structure 100 shown in FIG. 29 taken along line Y₂-Y₂.

First, any remaining portions of the protective capping layer 158 and remaining portions of the top semiconductor layer 114 are removed according to known techniques. Specifically, remaining portions of both the protective capping layer 158 and the top semiconductor layer 114 are removed selective to the surrounding materials, such as the placeholders 116, the isolation liner 122, and the stack spacers 126.

Next, the backside dielectric 166 is deposited according to known techniques. Specifically, a backside dielectric material is blanket deposited across the structure 100 including within any openings created by removing remaining portions of the protective capping layer 158 and the top semiconductor layer 114. After deposition, known chemical mechanical polishing may be used to remove excess portions of the backside dielectric material from bottom surfaces of the structure 100. After polishing, bottommost surfaces of the backside dielectric 166 are flush, or substantially flush with bottommost surfaces of the self-aligned backside gate cut dielectric 162 and the backside isolation features 164, as illustrated.

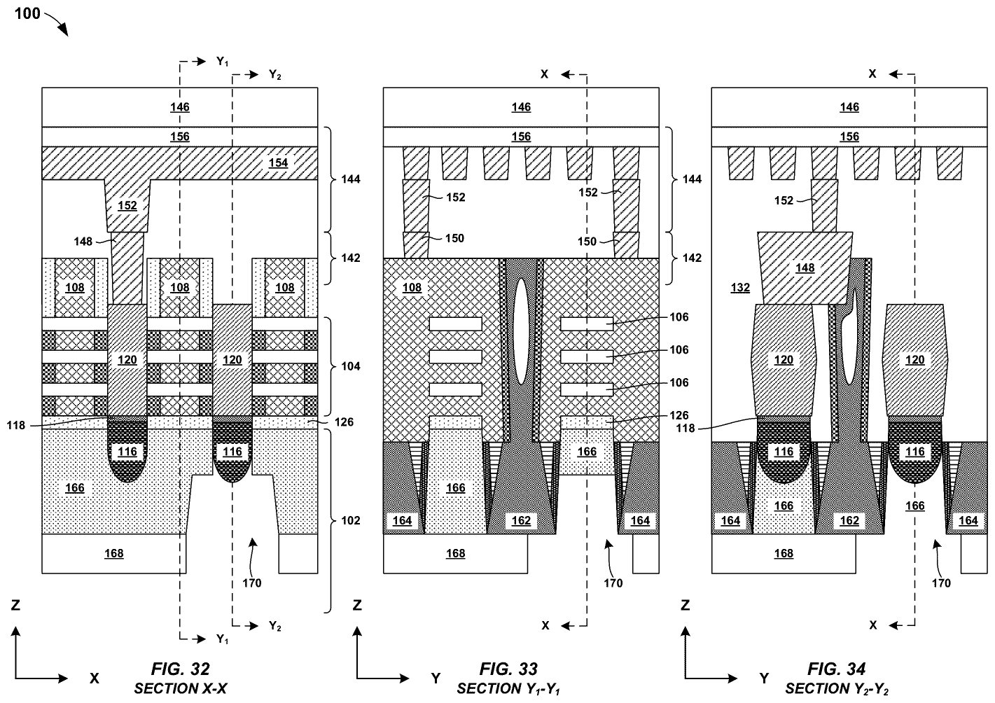

Referring now to FIGS. 32, 33, and 34, the structure 100 is shown after forming a backside contact mask 168 and backside contact trenches 170 according to an embodiment of the invention. FIG. 32 depicts a cross-sectional view of the structure 100 shown in FIGS. 33 and 34 taken along line X-X, FIG. 33 depicts a cross-sectional view of the structure 100 shown in FIG. 32 taken along line Y₁-Y₁, and FIG. 34 depicts a cross-sectional view of the structure 100 shown in FIG. 32 taken along line Y₂-Y₂.

First, a hard mask material is deposited on the structure 100. According to an exemplary embodiment, the hard mask material is deposited onto the backside of the structure 100, and then patterned into a plurality of individual hard masks, hereinafter the backside contact mask 168. The backside contact mask 168, and subsequently formed backside contact trenches 170, define positions or locations of future backside contacts.

Next, the pattern created by the backside contact mask 168 is transferred into the backside dielectric 166, as illustrated. Specifically, portions of the backside dielectric 166 are etched or removed selective to the self-aligned backside gate cut dielectric 162, the backside isolation features 164, the placeholders 116, and the isolation liner 122, as illustrated. The portions of the backside dielectric 166 can be removed using a silicon RIE process.

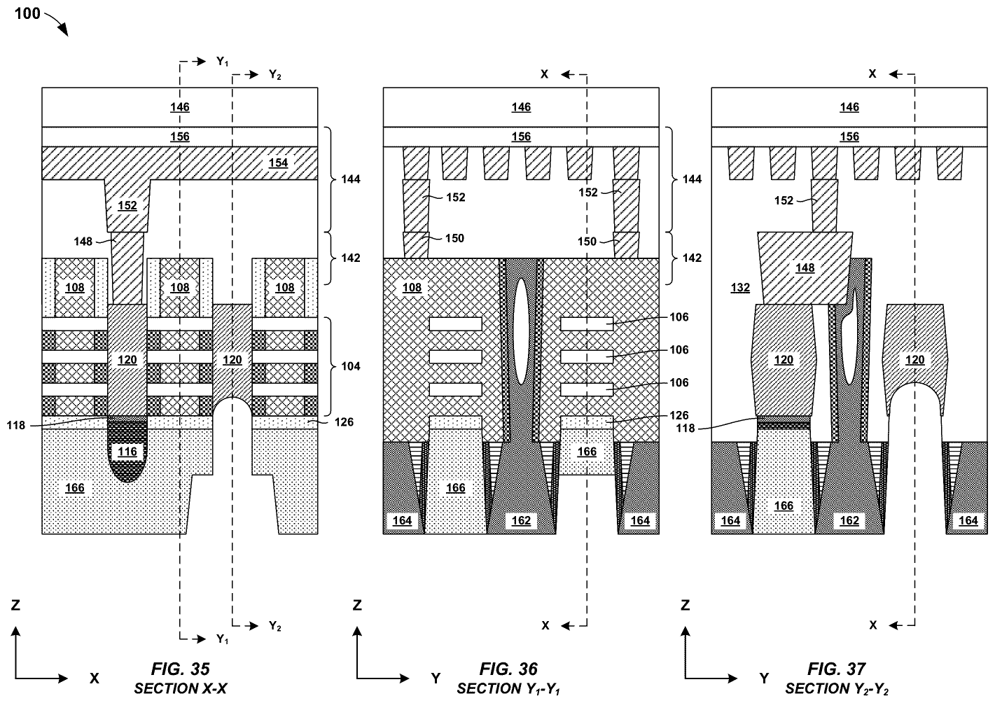

Referring now to FIGS. 35, 36, and 37, the structure 100 is shown after removing the placeholders 116 exposed by the backside contact trenches 170 according to an embodiment of the invention. FIG. 35 depicts a cross-sectional view of the structure 100 shown in FIGS. 36 and 37 taken along line X-X, FIG. 36 depicts a cross-sectional view of the structure 100 shown in FIG. 35 taken along line Y₁-Y₁, and FIG. 37 depicts a cross-sectional view of the structure 100 shown in FIG. 35 taken along line Y₂-Y₂.

The placeholders 116 exposed by the backside contact trenches 170 are selectively removed according to known techniques. Specifically, the placeholders 116 exposed by the backside contact trenches 170 are etched or removed selective to the backside dielectric 166, the stack spacers 126, the source drain regions 120, and the dielectric layer 132, as illustrated. The exposed placeholders 116 can be removed using a RIE process. Additionally, the buffer layers 118 exposed by removing the placeholders 116 are subsequently removed selective to the surrounding structures according to known techniques. In doing so, certain of the source drain regions 120 are exposed from the backside, as illustrated.

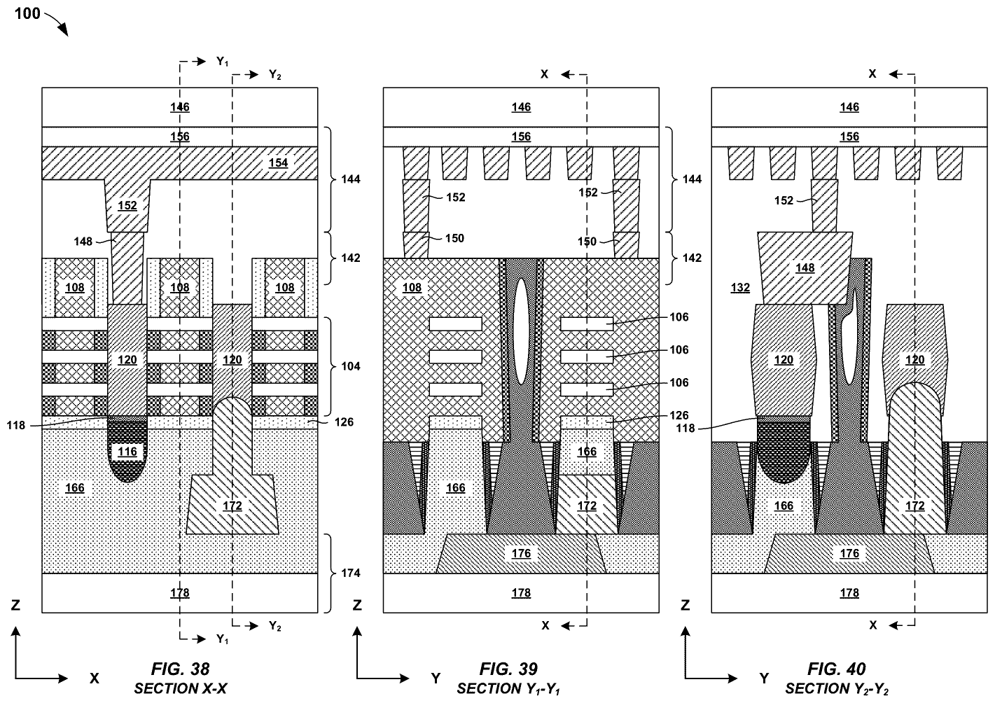

Referring now to FIGS. 38, 39, and 40, the structure 100 is shown after forming backside contact structures 172 and backside wiring layers 174 according to an embodiment of the invention. FIG. 35 depicts a cross-sectional view of the structure 100 shown in FIGS. 36 and 37 taken along line X-X, FIG. 36 depicts a cross-sectional view of the structure 100 shown in FIG. 35 taken along line Y₁-Y₁, and FIG. 37 depicts a cross-sectional view of the structure 100 shown in FIG. 35 taken along line Y₂-Y₂.

The backside contact trenches 170 are then filled with a conductive material to form the backside contact structures 172 according to known techniques. The backside contact structures 172 may include any suitable conductive material, such as, for example, copper, ruthenium, aluminum, tungsten, cobalt, or alloys thereof. In some embodiments, a metal silicide is formed at the bottom of the backside contact trenches 170 prior to filling them with the conductive material. After, excess conductive material can be polished using known techniques until bottommost surfaces of the backside contact structures 172 are flush, or substantially flush, with bottommost surfaces of the backside dielectric 166, as illustrated. It is noted, the backside contact structures 172 may include, for example, backside source drain contacts, as illustrated, as well as backside gate contacts (not shown).

After forming the backside contact structures 172, the backside wiring layers 174 are subsequently formed according to known techniques. The backside wiring layers 174 typically include at least backside power rails 176 and a backside power delivery network 178.

With continued reference to FIGS. 38, 39, and 40, and according to an embodiment, the structure 100 includes a first nanosheet transistor device, a second nanosheet transistor device, a dielectric gate cut structure between and electrically isolating the first nanosheet transistor device from the second nanosheet transistor device, where a first portion of the dielectric gate cut structure includes a positive tapered profile, and a second portion of the dielectric gate cut structure includes a negative tapered profile.

With continued reference to FIGS. 38, 39, and 40, and according to an embodiment, the structure further includes an air gap embedded within the dielectric gate cut structure.

With continued reference to FIGS. 38, 39, and 40, and according to an embodiment, the structure further includes signal lines directly above the dielectric gate cut structure in a cell boundary.

With continued reference to FIGS. 38, 39, and 40, and according to an embodiment, the structure further includes source drain contact above and directly contacting a source drain region, wherein the source drain contact extends laterally into the dielectric gate cut structure.

With continued reference to FIGS. 38, 39, and 40, and according to an embodiment the second portion of the dielectric gate cut structure is embedded within a shallow trench isolation region.

With continued reference to FIGS. 38, 39, and 40, and according to an embodiment the second portion of the dielectric gate cut structure directly contacts a portion of a backside contact structure.

With continued reference to FIGS. 38, 39, and 40, and according to an embodiment a smallest width of the second portion of the dielectric gate cut structure is greater than a smallest width of the first portion of the dielectric gate cut structure.

With continued reference to FIGS. 62, 63, and 64, and according to an embodiment, the structure 100 includes a first nanosheet stack, a second nanosheet stack, a self-aligned gate cut structure between and electrically isolating a first gate associated with the first nanosheet stack and a second gate associated with the second nanosheet stack, where a first portion of the self-aligned gate cut structure has a positive tapered profile, and a second portion of the self-aligned gate cut structure has a negative tapered profile.

With continued reference to FIGS. 62, 63, and 64, and according to an embodiment, the structure 100 includes first set of nanosheet channels surrounded by a first gate structure, second set of nanosheet channels surrounded by a second gate structure, a self-aligned gate cut structure between and electrically isolating the first gate structure from the second gate structure, where a first portion of the self-aligned gate cut structure has a positive tapered profile, and a second portion of the self-aligned gate cut structure has a negative tapered profile, and where a topmost surface of the second portion of the self-aligned gate cut structure is substantially flush with topmost surfaces of adjacent shallow trench isolation regions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
a first nanosheet transistor device;
a second nanosheet transistor device;
a dielectric gate cut structure between and electrically isolating the first nanosheet transistor device from the second nanosheet transistor device,
wherein a first portion of the dielectric gate cut structure comprises a positive tapered profile, and a second portion of the dielectric gate cut structure comprises a negative tapered profile.

2. The semiconductor structure according to claim 1, further comprising:
an air gap embedded within the dielectric gate cut structure.

3. The semiconductor structure according to claim 1, further comprising:
signal lines directly above the dielectric gate cut structure in a cell boundary.

4. The semiconductor structure according to claim 1, further comprising:
a source drain contact above and directly contacting a source drain region, wherein the source drain contact extends laterally into the dielectric gate cut structure.

5. The semiconductor structure according to claim 1, wherein the second portion of the dielectric gate cut structure is embedded within a shallow trench isolation region.

6. The semiconductor structure according to claim 1, wherein the second portion of the dielectric gate cut structure directly contacts a portion of a backside contact structure.

7. The semiconductor structure according to claim 1, wherein a smallest width of the second portion of the dielectric gate cut structure is greater than a smallest width of the first portion of the dielectric gate cut structure.

8. A semiconductor structure comprising:
a first nanosheet stack;
a second nanosheet stack;
a self-aligned gate cut structure between and electrically isolating a first gate associated with the first nanosheet stack and a second gate associated with the second nanosheet stack,
wherein a first portion of the self-aligned gate cut structure comprises a positive tapered profile, and a second portion of the self-aligned gate cut structure comprises a negative tapered profile.

9. The semiconductor structure according to claim 8, further comprising:
an air gap embedded within the self-aligned gate cut structure.

10. The semiconductor structure according to claim 8, further comprising:
signal lines directly above the self-aligned gate cut structure in a cell boundary.

11. The semiconductor structure according to claim 8, further comprising:
a source drain contact above and directly contacting a source drain region, wherein the source drain contact extends laterally into the self-aligned gate cut structure.

12. The semiconductor structure according to claim 8, wherein the second portion of the self-aligned gate cut structure is embedded within a shallow trench isolation region.

13. The semiconductor structure according to claim 8, wherein the second portion of the self-aligned gate cut structure directly contacts a portion of a backside contact structure.

14. The semiconductor structure according to claim 8, wherein a smallest width of the second portion of the self-aligned gate cut structure is greater than a smallest width of the first portion of the self-aligned gate cut structure.

15. A semiconductor structure comprising:
first set of nanosheet channels surrounded by a first gate structure;
second set of nanosheet channels surrounded by a second gate structure;
a self-aligned gate cut structure between and electrically isolating the first gate structure from the second gate structure,
wherein a first portion of the self-aligned gate cut structure comprises a positive tapered profile, and a second portion of the self-aligned gate cut structure comprises a negative tapered profile, and
wherein a topmost surface of the second portion of the self-aligned gate cut structure is substantially flush with topmost surfaces of adjacent shallow trench isolation regions.

16. The semiconductor structure according to claim 15, further comprising:
an air gap embedded within the self-aligned gate cut structure.

17. The semiconductor structure according to claim 15, further comprising:
signal lines directly above the self-aligned gate cut structure in a cell boundary.

18. The semiconductor structure according to claim 15, further comprising:
a source drain contact above and directly contacting a source drain region, wherein the source drain contact extends laterally into the self-aligned gate cut structure.

19. The semiconductor structure according to claim 15, wherein the second portion of the self-aligned gate cut structure is embedded within a shallow trench isolation region.

20. The semiconductor structure according to claim 15, wherein a smallest width of the second portion of the self-aligned gate cut structure is greater than a smallest width of the first portion of the self-aligned gate cut structure.
